(19) United States
(12) Patent Application Publication
(10) Pub. No.: US 2007/0200259 A1
(43) Pub. Date: Aug. 30, 2007

(54) Touch panel

(76) Inventors: Akira Nakanishi, Fukui (JP); Tetsuo Murakami, Fukui (JP); Kenichi Matsumoto, Osaka (JP); Shoji Fujii, Osaka (JP)

Correspondence Address: WENDEROTH, LIND & PONACK L.L.P., 2033 K. STREET, NW, SUITE 800, WASHINGTON, DC, 20006, US

(21) Appl. No.: 11/704,960

(22) Filed: Feb. 12, 2007

(30) Foreign Application Priority Data
Feb. 28, 2006 (JP) 2006-051713

(51) Int. Cl. H01L 23/544

(52) U.S. Cl. 257/797

(57) ABSTRACT

The touch panel of the invention includes an optically transparent upper substrate having an upper conductive layer formed on an undersurface thereof, an optically transparent lower substrate having a lower conductive layer formed on an upper surface thereof and facing the upper conductive layer with a predetermined space, a spacer in a frame shape disposed between the upper substrate and the lower substrate, and a polarizing plate adhered to an upper surface of the upper substrate, in which the polarizing plate is adhered to the upper surface of the upper substrate within the outer periphery of the spacer. Because the polarizing plate is attached to the upper surface of the upper substrate but within an outer periphery of the spacer, even when the panel is exposed to a high temperature and high humidity environment, the substrate is prevented from being peeled off the spacer and a loose fitness of wiring substrate is avoided, thus a touch panel of an easy operation and a secure electrical connection is obtained.

### FIELD OF THE INVENTION

This invention relates to a touch panel which is used mainly for operating various electronic devices.

### BACKGROUND OF THE INVENTION

In recent years, an electronic device including a portable phone and a car navigator tends to require much higher and a variety of functions. With this trend, a device having an optically transparent touch panel installed on a front panel of a display element such as a liquid crystal is increasing in number, in which the variety of functions is switched with the touch panel pressed by a finger or a pen, meanwhile a display of a display element can be recognized in a rear side of the panel.

Following, such a conventional touch panel is explained with reference to FIG. 3. For easy understanding of its constitution, thickness of the panel is illustrated enlarged in the drawing.

FIG. 3 is a cross sectional view of a conventional touch panel. In FIG. 3, upper substrate 1 and lower substrate 2 are a transparent substrate. On an undersurface of upper substrate 1, optically transparent upper conductive layer 3 is formed, and on an upper surface of lower substrate 2, optically transparent lower conductive layer 4 is formed.

On a surface of lower conductive layer 4, dot spacers (not illustrated) are formed at predetermined intervals. At both ends of a side of upper conductive layer 3, a pair of upper electrodes 3A is formed, and a pair of under electrodes 4A is correspondingly formed at both ends of a side of lower conductive layer 4. Outer peripheries of upper substrate 1 and lower substrate 2 are attached with adhesive layers formed on upper and lower surfaces of spacer 5 (not illustrated), with upper conductive layer 3 and lower conductive layer 4 facing at a predetermined distance.

Wiring substrate 6 is in a film shape. Wiring patterns 6A and 6B are formed on upper and lower surface of wiring substrate 6. A surface of wiring patterns 6A and of 6B is entirely covered by a film-like cover sheet (not illustrated) except for right and left ends.

A left end of wiring substrate 6 is held by a right end of upper substrate 1 and of a lower substrate 2. A terminal portion of under electrode 4A is extendedly formed on an upper surface of lower substrate 2 and is adhered to a left terminal portion of wiring pattern 6B, electrically connected. Similarly, a terminal portion of upper electrode 3A is extendedly formed on an under surface of upper substrate 1 and is adhered to a left terminal portion of wiring pattern 6A, electrically connected.

Polarizing plate 7 is a polarizing material covered by triaccetylcellulose film. Polarizing plate 7 is adhered to an upper surface of upper substrate 1 with an adhesive layer (not illustrated) applied to an under surface of the polarizing plate.

Thus constituted touch panel is placed on a front panel of a display such as a liquid crystal and is installed on an electronic device, with wiring substrate 6 bent down and a right terminal of wiring patterns 6A and 6B connected to an electronic circuit (not illustrated) of the electronic device through a connector or by soldering.

With above constitution, when a surface of polarizing plate 7 is pressed by a finger or a pencil, substrate 1 bends with polarizing plate 7 contacting upper conductive layer 3 with lower conductive layer 4 at the depressed point, meanwhile a display of the liquid crystal display element can be recognized at a rear side of touch panel.

Voltage is applied in sequence from the electric circuit to upper conductive layer 3 and lower conductive layer 4 through wiring patterns 6A and 6B on wiring substrate 6. The electronic circuit detects the depressed point by the voltages, switching a variety of functions of the device.

When sunlight or external light incoming from above passes through polarizing plate 7, one of light waves in X direction and in Y direction crossing the X direction at right angle is filtered by polarizing plate 7, and a linearly polarized wave comes into upper substrate 1 filtered by polarizing plate 7.

The light passing through upper substrate 1 is reflected upward by lower conductive layer 4. However, because the amount of incoming light is reduced by about half by polarizing plate 7, reflected light going out through the upper surface of polarizing plate 7 is thereby reduced and the liquid crystal display element at a rear side is easily recognized.

As a prior art document related to this invention, Unexamined Japanese Patent Publication Number 2006-11598 is published as an example.

With above conventional touch panel, however, polarizing plate 7 is formed by drawing, composed of plural materials laminated, and is easily contractible with heat, and which is attached to the surface of upper substrate 1 made of different material. Because of the structure, when the panel is exposed to a high temperature and high humidity environment, upper substrate 1 bends with contracted polarizing plate 7, peeling off an outer periphery of the substrate from spacer 5, and causing an operation unstable. Bent substrate 1 also makes electrical connection insecure between wiring pattern 6A of wiring substrate 6 and upper electrode 3A. The conventional touch panel contains above mentioned problems.

### SUMMARY OF THE INVENTION

With the touch panel of the invention, a polarizing plate is adhered to an upper surface of an upper substrate but within an outer periphery of a frame-like spacer. Because the polarizing plate is placed inside the outer periphery of the spacer, the substrate bends little even when the panel is exposed to a high temperature and high humidity environment, preventing the substrate from being peeled off from the spacer and avoiding a loose fitness between the substrate and wiring substrate 6, providing a touch panel of easy operation and secure electrical connection.

The touch panel of the invention includes an optically transparent upper substrate having an upper conductive layer formed on an undersurface thereof, an optically transparent lower substrate having a lower conductive layer formed on an upper surface thereof and facing the upper conductive layer with a predetermined space, a spacer in a frame shape disposed between the upper substrate and the lower substrate, and a polarizing plate adhered to an upper surface of the upper substrate, in which the polarizing plate is adhered to the upper surface of the upper substrate within the outer periphery of the spacer.

### BRIEF DESCRIPTION OF THE DRAWINGS

FIG. 1 is across sectional view of a touch panel according to an exemplary embodiment of the invention.

FIG. 2 is a cross sectional view of other touch panel according to the exemplary embodiment of the invention.

FIG. 3 is a cross sectional view of a conventional touch panel.

### DETAILED DESCRIPTION OF THE PREFERRED EMBODIMENTS

The invention solves the conventional problems and provides a touch panel with stable operational performance and electrical connection even when it is exposed to a high temperature and high humidity environment.

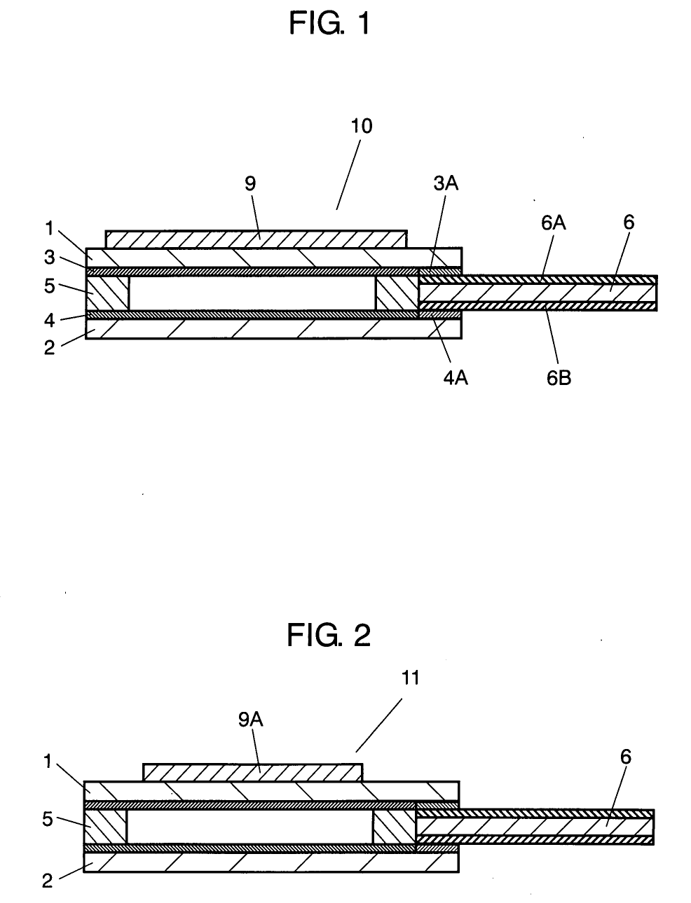

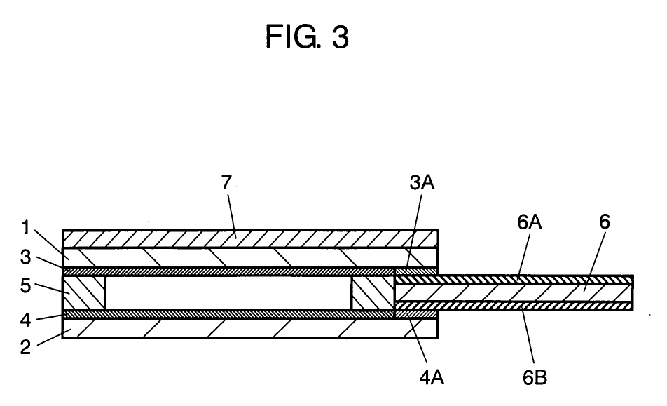

Following, an exemplary embodiment is explained with reference to FIGS. 1 and 2. Thickness is illustrated enlarged in the drawings for easy understanding of constitution.

For the part already explained in the background art, the same numerical reference is provided.

### Exemplary Embodiment

FIG. 1 is a cross sectional view of a touch panel according to an exemplary embodiment of the invention. In FIG. 1, upper substrate 1 is an optically isotropic and transparent substrate, a film made of plyestersulfone, polycycloolefin or the like. Lower substrate 2 is an optically isotropic and transparent substrate made of glass, polycarbonate, polyestersulfone or the like. Optically transparent upper conductive layer 3, made of indiumtin oxide, indium oxide or the like, is formed on an undersurface of upper substrate 1 by sputtering method for instance. Similarly, lower conductive layer 4 is formed on an upper surface of lower substrate 2 by sputtering method for instance.

A plurality of dot spacers made of insulating resin such as epoxy and silicone (not illustrated) is formed on an upper surface of lower conductive layer 4 at predetermined intervals. At both ends of a side of upper conductive layer 3, a pair of upper electrodes 3A made of silver, carbon or the like is formed, and a pair of under electrodes 4A is formed at both ends of a side of lower conductive layer 4 crossing upper electrodes 3A at right angles.

Spacer 5 is formed in a frame shape and is made of polyester, epoxy or the like. An adhesive layer (not illustrated) made of acryl, rubber or the like is applied to upper and lower sides or a side of spacer 5 attaching outer peripheries of upper substrate 1 and lower substrate 2, facing conductive layer 3 and lower conductive layer 4 at a predetermined space.

Wiring substrate 6 is a film of polyethyrene terephthalate, polyamide or the like. Wiring patterns 6A and 6B are made of copper, silver, carbon or the like and are formed on an upper and a lower surface of the wiring substrate. A surface of wiring patterns 6A and 6B is entirely covered by a film-like cover sheet (not illustrated) except for right and left ends.

A left end of wiring substrate 6 is held between right ends of upper substrate 1 and lower side substrate 2. A terminal portion of under-electrode 4A extendedly formed on an upper surface of lower substrate 2 and a left terminal portion of wiring pattern 6B are adhered with an anisotropic conductive adhesive (not illustrated), a synthetic resin dispersed with conductive particles, and are electrically connected. Similarly, a terminal portion of upper electrode 3A extendedly formed on an under surface of upper substrate 1 and a left terminal portion of wiring pattern 6A are adhered with the anisotropic conductive adhesive (not illustrated), the synthetic resin dispersed with conductive particles, and are electrically connected.

Polarizing plate 9 is made of polarizing material, iodine or dye adsorbed by polyvinyl alcohol, drawn and oriented, and then is covered by triaccetylcellulose film. Polarizing plate 9 is made smaller than upper substrate 1 in front, behind, left and right dimensions. Polarizing plate 9 is attached to an upper surface of upper substrate 1 but within an outer periphery of frame-like spacer 5 with an adhesive layer (not illustrated) applied to an under surface of the polarizing plate, constituting touch panel 10.

Thus constituted touch panel 10 is placed on a front part of a liquid crystal or other display element and is installed in an electronic device, with wiring substrate 6 bent down and a right terminal of wiring patterns 6A and 6B connected to an electronic circuit (not illustrated) of the electronic device through a connector or by soldering.

With above constitution, when a surface of polarizing plate 9 is pressed by a finger or by a pencil, substrate 1 bends with polarizing plate 9, contacting upper conductive layer 3 and lower conductive layer 4 at the depressed point, meanwhile a display of the liquid crystal display element is recognized at a rear side of touch panel 10.

The voltage is applied sequentially from the electric circuit to upper conductive layer 3 and lower conductive layer 4 through wiring patterns 6A and 6B on wiring substrate 6. The electronic circuit detects the depressed point with the voltages, switching a variety of functions of the device.

When sunlight or external light incoming from above passes through polarizing plate 9, either one of light waves in X direction and in Y direction crossing the X direction at right angle is filtered by polarizing plate 9, becoming a linearly polarized wave and then coming into upper substrate 1 through polarizing plate 9.

The linearly polarized wave passing through upper substrate 1 is reflected upward mainly by upper conductive layer 3, lower conductive layer 4 and under lower-substrate 2. However, because the amount of incoming light is reduced by about half by polarizing plate 9, the light reflected and going out through an upper surface of polarizing plate 9 is reduced, and the liquid crystal display element at a rear side is easily recognized.

Polarizing plate 9, produced by drawing, composed of plural materials laminated and is easily contractible with applied heat, is attached to the surface of upper substrate 1 made of different material. However, because polarizing plate 9 is formed smaller than upper substrate 1 in front, behind, left and right dimensions, and attached to upper substrate 1 within the outer periphery of frame-like space 5, even when it is exposed to a high temperature and high humidity environment, upper substrate 1 adhered to polarizing plate 9 bends little.

That is, polarizing plate 9 contracts in a high temperature and high humidity environment, bending upper substrate 1. But, since polarizing plate 9 is attached to upper substrate 1 within the outer periphery of spacer 5, the contracting force of the plate is applied to substrate 1 not entirely but only partially, bending substrate 1 only to a small extent. As a result, substrate 1 is prevented from being peeled off spacer 5 at a peripheral part of the substrate, and a loose fitness between wiring pattern 6A of wiring substrate 6 and upper electrode 3A is avoided.

Thus, in the exemplary embodiment of the invention, because polarizing plate 9 is attached to the upper surface of upper substrate 1 within the outer periphery of frame-like spacer 5, bending of upper substrate 1 is kept small even when the panel is exposed to a high temperature and high humidity environment. Thus, substrate 1 is prevented from being peeled off spacer 5 and a loose fitness of wiring substrate 6 is avoided, providing a touch panel of easy operation and secure electrical connection.

FIG. 2 is a cross sectional view of other touch panel of the invention. A difference in FIG. 2 from FIG. 1 is in polarizing plate 9A, so polarizing plate 9A is mainly explained and explanation other part than plate 9A is omitted.

As shown in FIG. 2, polarizing plate 9A of touch panel 11 is formed much smaller than the polarizing plate in FIG. 1 in outline dimensions, and such touch panel is attached to upper substrate 1 within an inner periphery of spacer 5. Because of this constitution, bending of upper substrate 1 is kept much smaller.

In above explanation, polarizing plate 9 or polarizing plate 9A is attached to the surface of upper substrate 1. Instead, upper substrate 1 and lower substrate 2 can be made of a bendable phase-difference plate, a polycarbonate or cycloolefin film drawn to have a double refractivity and a phase difference of ¼ wavelength, embodying the invention. The phase-difference plate can be put between polarizing plate 9 and upper substrate 1 for embodiment. The phase difference-plate can be attached to an undersurface of lower substrate 2, still embodying the invention.

As explained, the touch panel of the invention is provided with an advantageous effect, dependable operability and electrical connection, so is useful for a variety of electronic devices.

What is claimed is:

1. A touch panel comprising:
an optically transparent upper substrate having an upper conductive layer formed on an undersurface thereof;
an optically transparent lower substrate having a lower conductive layer formed on an upper surface thereof, facing the upper conductive layer with a predetermined space;
a spacer in a frame shape being disposed between the upper substrate and the lower substrate; and
a polarizing plate being adhered to an upper surface of the upper substrate,
wherein the polarizing plate is being adhered within an outer periphery of the spacer.
